(19) United States
(12) Patent Application Publication
(10) Pub. No.: US 2016/0172414 A1
(43) Pub. Date: Jun. 16, 2016

(54) RADIATION IMAGING APPARATUS, METHOD OF MANUFACTURING THE SAME, AND RADIATION INSPECTION APPARATUS

(71) Applicant: CANON KABUSHIKI KAISHA, Tokyo (JP)

(72) Inventors: Shoshiro Saruta, Kodama-gun (JP); Yoshito Sasaki, Kumagaya-shi (JP); Satoshi Okada, Tokyo (JP); Kazumi Nagano, Honjo-shi (JP); Yohei Ishida, Honjo-shi (JP)

(21) Appl. No.: 15/047,928

(22) Filed: Feb. 19, 2016

Related U.S. Application Data
(63) Continuation of application No. PCT/JP2014/003741, filed on Jul. 15, 2014.

(30) Foreign Application Priority Data
Sep. 26, 2013 (JP) 2013-200524

(51) Int. Cl. H01L 27/146

(52) U.S. Cl. CPC H01L 27/14663

(57) ABSTRACT

A radiation imaging apparatus, comprising a plurality of sensor units each including a plurality of sensors, a support portion having a lattice shape which partitions a region under the plurality of sensor units into a plurality of spaces and configured to support the plurality of sensor units from a side of lower surfaces of the plurality of sensor units, and bonding members respectively arranged in the plurality of spaces and configured to bond the plurality of sensor units and the support portion.

This application is a continuation of International Patent Application No. PCT/JP2014/003741 filed on Jul. 15, 2014, and claims priority to Japanese Patent Application No. 2013-200524 filed on Sep. 26, 2013, the entire content of both of which is incorporated herein by reference.

### BACKGROUND OF THE INVENTION

1. Technical Field

The present invention relates to a radiation imaging apparatus, a method of manufacturing the same, and a radiation inspection apparatus.

2. Background Art

A radiation imaging apparatus comprises a plurality of sensor units each including a plurality of sensors and a support portion (base) which supports the plurality of sensor units. With this arrangement, a large sensor panel can be formed. As exemplified in PTL 1, each sensor unit and the support portion are bonded by a bonding member such as a resin having an adhesive force.

Even if each of the plurality of sensor units normally operates before it is arranged on the support portion, it may fail due to an external factor such as static electricity after it is arranged on the support portion. After the plurality of sensor units are arranged on the support portion and before another process (for example, a process of forming a scintillator on the plurality of sensor units), an inspection is performed whether each sensor unit normally operates. As a result of the inspection, when some of the plurality of sensor units have failed, these sensor units are removed to replace them with other sensor units. This removal is performed using, for example, a chemical agent for dissolving the bonding member to member which bonds each sensor unit and the support portion). For this reason, it is not easy to selectively remove only a sensor unit serving as a removal target. Sensor units other than the removal target may be peeled.

On the other hand, PTL 2 discloses a structure capable of removing some of the plurality of sensor units from the support portion by adhering each sensor unit and the support portion by using a heat-peeling adhesive member. Since this adhesive member has a heat-peeling property, the adhesive force of the adhesive member degrades due to heating during the manufacturing process. As a result, a sensor unit other than the removal target may be peeled.

### CITATION LIST

### Patent Literature

PTL 1: Japanese Patent Laid-Open No. 2008-224429
PTL 2: Japanese Patent Laid-Open No. 2012-145474

### SUMMARY OF INVENTION

### Technical Problem

It is an object of the present invention to Provide a technique advantageous in selectively removing some sensor units from a support portion which supports a plurality of sensor units.

### Solution to Problem

According to an aspect of the present invention, there is provided the radiation imaging apparatus comprising a plurality of sensor units each including a plurality of sensors, a support portion having a lattice shape which partitions a region under the plurality of sensor units into a plurality of spaces and configured to support the plurality of sensor units from a side of lower surfaces of the plurality of sensor units, and bonding members respectively arranged in the plurality of spaces and configured to bond the plurality of sensor units and the support portion.

### Advantageous Effects of Invention

The present invention is advantageous in selectively removing some sensor units from the support portion which supports the plurality of sensor units.

Further features of the present invention will become apparent from the following description of exemplary embodiments (with reference to the attached drawings).

### BRIEF DESCRIPTION OF DRAWINGS

The accompanying drawings, which are incorporated in and constitute a part of the specification, illustrate exemplary embodiments of the invention and, together with the description, serve to explain the principles of the present invention.

FIG. 1A is a view used for explaining an arrangement example of a radiation imaging apparatus;

FIG. 1B is a view used for explaining the arrangement example of the radiation imaging apparatus;

FIG. 1C is a view used for explaining the arrangement example of the radiation imaging apparatus;

FIG. 2A is a view for explaining an arrangement example of a support portion of the radiation imaging apparatus;

FIG. 2B is a view for explaining the arrangement example of the support portion of the radiation imaging apparatus;

FIG. 2C is a view for explaining the arrangement example of the support portion of the radiation imaging apparatus;

FIG. 2D is a view for explaining the arrangement example of the support portion of the radiation imaging apparatus;

FIG. 2E is a view for explaining the arrangement example of the support portion of the radiation imaging apparatus;

FIG. 2F is a view for explaining the arrangement example of the support portion of the radiation imaging apparatus;

FIG. 3A is a view for explaining another arrangement example of the support portion of the radiation imaging apparatus;

FIG. 3B is a view for explaining the other arrangement example of the support portion of the radiation imaging apparatus;

FIG. 4 is a view for explaining an example of a method of removing some sensor units;

FIG. 5A is a view for explaining another arrangement example of a support portion of a radiation imaging apparatus;

FIG. 5B is a view for explaining the other arrangement example of the support portion of the radiation imaging apparatus;

FIG. 5C is a view for explaining the other arrangement example of the support portion of the radiation imaging apparatus;

FIG. 5D is a view for explaining the other arrangement example of the support portion of the radiation imaging apparatus;

FIG. 5E is a view for explaining the other arrangement example of the support portion of the radiation imaging apparatus;

FIG. 5F is a view for explaining the other arrangement example of the support portion of the radiation imaging apparatus;

FIG. 5G is a view for explaining the other arrangement example of the support portion of the radiation imaging apparatus;

FIG. 6A is a view for explaining still another arrangement example of a support portion of a radiation imaging apparatus;

FIG. 6B is a view for explaining still other arrangement example of the support portion of the radiation imaging apparatus;

FIG. 6C is a view for explaining still other arrangement example of the support portion of the radiation imaging apparatus;

FIG. 6D is a view for explaining still other arrangement example of the support portion of the radiation imaging apparatus;

FIG. 7A is a view for explaining still another arrangement example of a support portion of a radiation imaging apparatus;

FIG. 7B is a view for explaining still other arrangement example of the support portion of the radiation imaging apparatus;

FIG. 7C is a view for explaining still other arrangement example of the support portion of the radiation imaging apparatus;

FIG. 7D is a view for explaining still other arrangement example of the support portion of the radiation imaging apparatus;

FIG. 7E is a view for explaining still other arrangement example of the support portion of the radiation imaging apparatus;

FIG. 7F is a view for explaining still other arrangement example of the support portion of the radiation imaging apparatus;

FIG. 7G is a view for explaining still other arrangement example of the support portion of the radiation imaging apparatus;

FIG. 8 is a view for explaining an arrangement example of a radiation inspection apparatus;

FIG. 9A is a view for explaining a comparative example of a radiation imaging apparatus;

FIG. 9B is a view for explaining the comparative example of the radiation imaging apparatus;

FIG. 9C is a view for explaining the comparative example of the radiation imaging apparatus;

FIG. 9D is a view for explaining the comparative example of the radiation imaging apparatus;

FIG. 10A is a view for explaining an arrangement example of a support portion of a radiation imaging apparatus;

FIG. 10B is a view for explaining the arrangement example of the support portion of the radiation imaging apparatus;

FIG. 10C is a view for explaining the arrangement example of the support portion of the radiation imaging apparatus;

FIG. 10D is a view for explaining the arrangement example of the support portion of the radiation imaging apparatus;

FIG. 11A is a view for explaining a method of manufacturing the radiation imaging apparatus;

FIG. 11B is a view for explaining the method of manufacturing the radiation imaging apparatus;

FIG. 12A is a view for explaining still another arrangement example of a support portion of a radiation imaging apparatus;

FIG. 12B is a view for explaining still other arrangement example of the support portion of the radiation imaging apparatus;

FIG. 13A is a view for explaining still another arrangement example of a support portion of a radiation imaging apparatus;

FIG. 13B is a view for explaining still other arrangement example of the support portion of the radiation imaging apparatus;

FIG. 14A is a view for explaining still another arrangement example of a support portion of a radiation imaging apparatus; and

FIG. 14B is a view for explaining still other arrangement example of the support portion of the radiation imaging apparatus.

### DESCRIPTION OF EMBODIMENTS

### First Embodiment

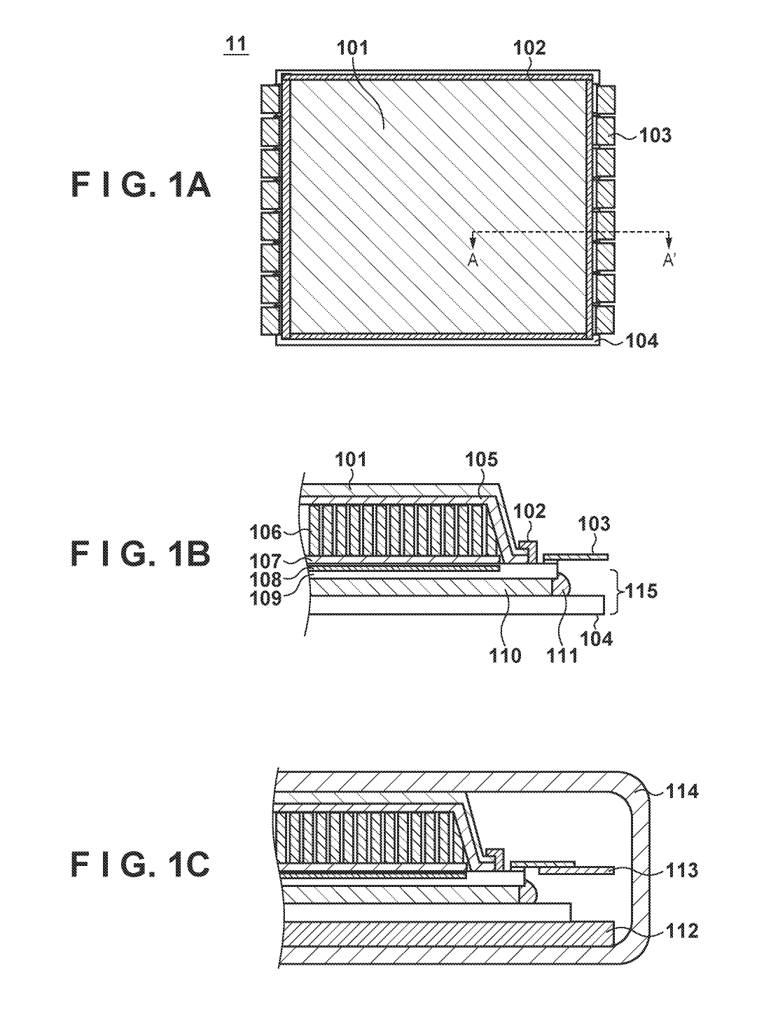

A radiation imaging apparatus 11 according to the first embodiment will be described with reference to FIGS. 1A to 4. FIGS. 1A to 1C are schematic views showing an arrangement example of the radiation imaging apparatus 11. FIG. 1A is a plan view of the radiation imaging apparatus 11. FIG. 1B shows the sectional structure along a outline A-A′ of FIG. 1A.

The radiation imaging apparatus 11 includes a base 104, a support portion 110 arranged on the base 104, and a plurality of sensor units 109 arranged on the support portion 110. In FIG. 1B, the base 104, the support portion 110, and the plurality of sensor units 109 altogether are illustrated as a sensor panel 115.

Each sensor unit 109 includes a sensor chip on which, for example, a plurality of sensors 108 are arranged, and each sensor 108 includes a CMOS image sensor. The sensor chip is obtained by forming, on a silicon wafer, the sensor 108 and a circuit (not shown) for reading out a signal from the sensor 108 and cutting the silicon wafer chip by chip by dicing. The sensor unit 109 need not be limited to the chip, but may form a predetermined unit. The sensor 108 is not limited to the CMOS sensor, but may include another sensor such as a PIN sensor or a MIS sensor.

The radiation imaging apparatus 11 further includes a scintillator 106 formed on the plurality of sensor units 109 via a sensor protective film 107, and a scintillator protective film 101 formed on the scintillator 106 via an adhesive member 105. The scintillator can be made of, for example, thallium-activated cesium iodide (CsI:Tl).

The end region of the scintillator protective film 101 is sealed by a member 102 to prevent the scintillator 106 from the moisture or the like. Similarly, the end region of the support portion 110 is sealed by a member 111. A moisture-proof material is used for the members 102 and 111. For example, an epoxy resin or polyvinylidene resin can preferably be used as the moisture-proof material.

An electrode portion for exchanging electrical signals and supplying a power supply voltage is arranged in the end region of each sensor unit 109. The electrode portion is connected to a flexible printed board 108.

Note that a heat-resistance member which can stand heat when forming the scintillator 106 in addition to properties of flatness and rigidity is used for the base 104. For example, a glass substrate of soda lime glass, non-alkali glass, or the like, a metal plate of aluminum or the like, or a substrate of CFRP (Carbon Fiber Reinforced Plastic), amorphous carbon, or the like can be used as the base 104.

FIG. 1C shows the sectional structure of the radiation imaging apparatus 11 mounted in a housing 114. The radiation imaging apparatus 11 is connected to a printed circuit board 113 via the flexible printed board 103. With the above arrangement, image data obtained by radiation imaging is read out.

More specifically, radiation passing through an object is transmitted through the housing 114, the scintillator protective film 101, and the adhesive member 105 and enters the scintillator 106. The radiation is converted into light by the scintillator 106. Each sensor 108 of each sensor unit 109 detects the light, and an electrical signal based on the radiation is obtained. An image processing unit (not shown) forms image data based on this electrical signal. Note that in addition to the scintillator protection function, the scintillator protective film 101 may also have a reflection function of reflecting light from the scintillator 106 toward the sensor panel 115.

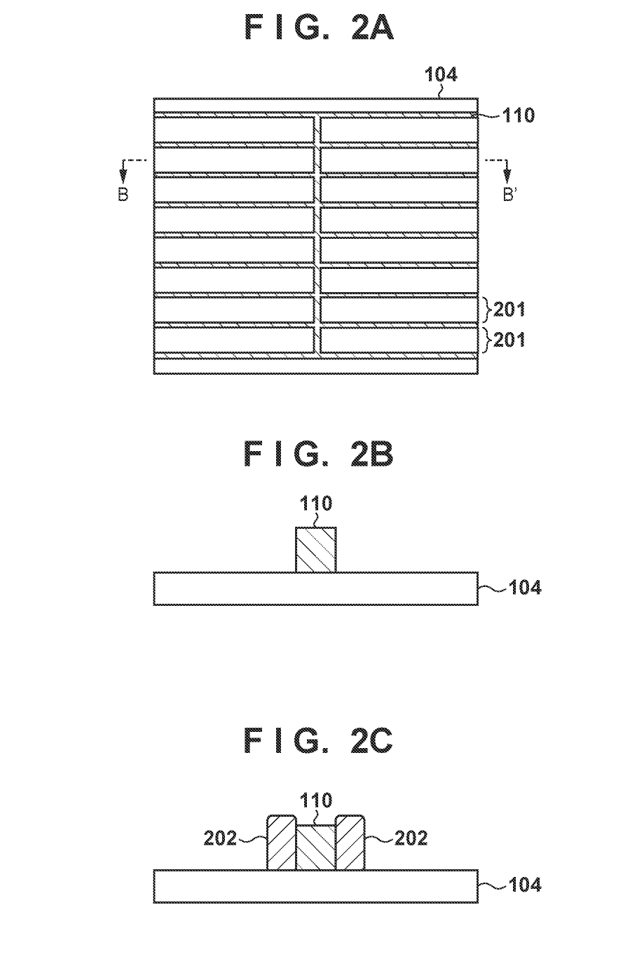

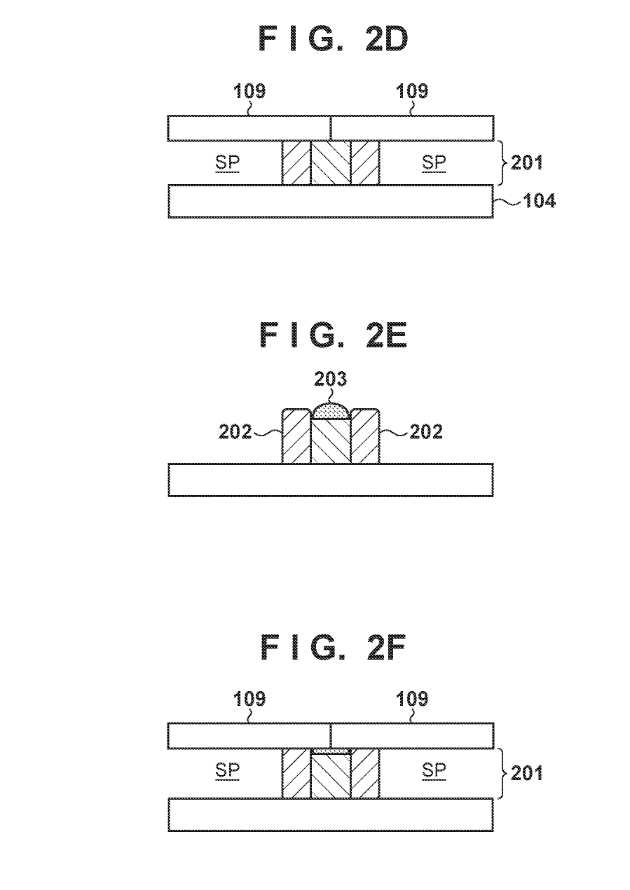

FIGS. 2A to 2F are schematic views showing the arrangement example of the base 104 and the support. portion 110. FIG. 2A exemplifies the arrangement of the base 104 and the support portion 110 when viewed from the above. The support portion 110 has a lattice shape for partitioning a region under the plurality of sensor units 109 into a plurality of spaces sp. FIGS. 2B to 2D are schematic views of the manufacturing steps of the sensor panel 115 for the sectional structure along a outline B-B′ of FIG. 2A.

First of all, as shown in FIG. 2B, the support portion 110 of the lattice shape is arranged on the base 104. The base 104 and the support portion 110 may be integrally formed. For example, a base with a support portion having an upper surface whose convex portion draws a lattice shape may be prepared. Note that the support portion 110 can be formed using a known manufacturing process, for example, a photoetching process, a sandblast method, a polishing method such as mechanical polishing or an injection molding method.

Next, as shown in FIG. 2C, adhesive members 202 are formed on the side surfaces of the support portion 110. Each adhesive member 202 functions as a bonding member for bonding the sensor unit 109 and the support portion 110 when arranging sensor unit 109 on the support portion 110 in the subsequent step. Each adhesive member 202 has the upper surface higher than the upper surface of the support portion 110. Note that each adhesive member 202 has a viscosity of, for example, 10 kPa·s so as to maintain the shape exemplified in FIG. 2C.

Finally, as exemplified in FIG. 2D, the sensor units 109 are arranged on the upper surface of the support portion 110, and fixed by the adhesive members 202. In this case, the plurality of sensor units 109 are arranged so that the boundary between the adjacent sensor units 109 comes close to the upper surface of the support portion 110.

As shown in FIGS. 2E and 2F, in order to adjust the levels of the support portion 110 and the adhesive members 202, an elastic member 203 may be arranged on the upper surface of the support portion 110. For example, a CEMEDINE PM series can be used as the elastic member 203. In this case, the elastic member 203 is applied to the upper surface of the support portion 110 before the adhesive members 202 are applied to the side surfaces of the support portion 110. After the elastic member 203 1s sufficiently dried to some extent that the elastic member 203 is not adhered to the sensor unit 109, the sensor units 109 are arranged. The elastic member 203 may have an adhering function and preferably has an adhesive force smaller than that of the adhesive members 202. The support portion 110 itself may be made of the same material as that of the elastic member 203. In this case, the upper surface of the adhesive members 202 may be lower than the upper surface of the support portion 110.

Spaces sp partitioned by the support portion 110 exist between the sensor units 109 and the base 104. Each space sp corresponds to each sensor unit 109. At the end region, each space sp is open by an opening 201 formed by the corresponding sensor unit 109, a base 110, and the base 104. A chemical agent to be referred to as a chemical agent P hereinafter) for dissolving each adhesive member 202 can be applied to each space sp through the corresponding opening 201.

For example, when removing some sensor units 109, the chemical agent P is injected to the spaces sp contacting the sensor units 109 serving as the removal targets. This makes it possible to individually remove the sensor units 109 as the removal targets out of the plurality of sensor units 109 from the support portion 110. That is, with the above arrangement, each of the plurality of sensor units 109 can be removed from the support portion 110 on the unit basis. The adhesive members 202 are arranged to join the sensor unit 109 and the support portion 110 and arranged to be dissolved by the chemical agent P injected into the spaces sp. Each adhesive member 202 need not be formed in the corresponding entire space sp.

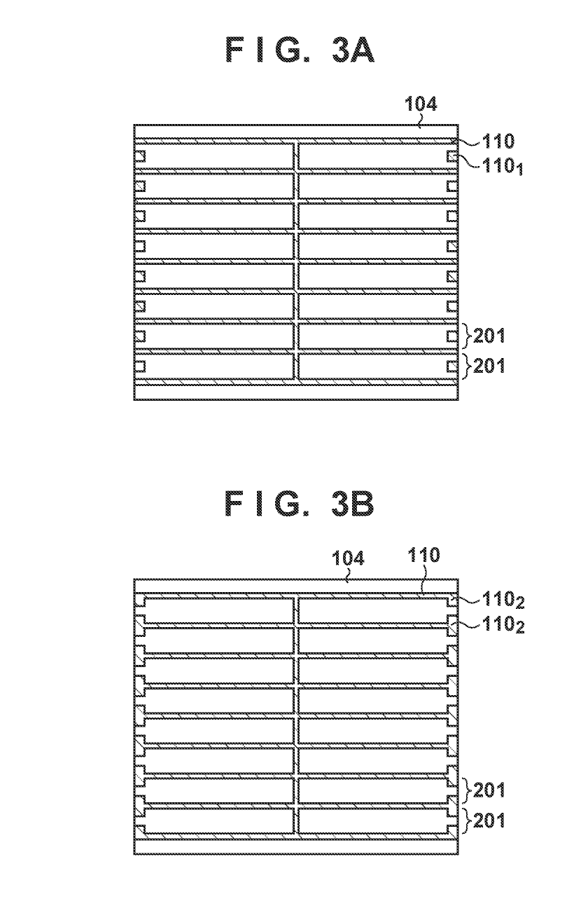

Each opening 201 can have a size which can receive the chemical agent P. For example, as shown in FIG. 3A, another support portion 110₁ may be arranged near the corresponding opening 201. Alternatively, as shown in FIG. 3B, the support portion 110 may have a portion 110₂ having a large width near the corresponding opening 201.

According to this embodiment, the scintillator 106 is formed by a deposition method (a so-called direct formation method) on the sensor panel 115 via the sensor protective film 107. The adhesive member 202 must have heat-resistance in addition to heat curability. The adhesive member 202 suffices to have heat resistance of, for example, 210° C. For example, an epoxy resin is used for the adhesive member 202. More specifically, TB2285 or TB2088E available from ThreeBond can be used for the adhesive member 202. In this case, to remove the sensor unit 109, a solvent such as acetone, cyclohexane, methyl ethyl ketone, methyl isobutyl ketone, or tetrahydrofuran can be used as the chemical agent P.

An adhesive material by which an adhesive force is generated by dehydration condensation of a silanol group or alkoxy group may be used as the adhesive member 202. More specifically, colloidal silica of SNOWTEX series available from Nissan Chemical industries can be used. Note that the adhesive member 202 may be dissolved with an aqueous resin such as Gohsenol available from NIPPON GOHSEI or polyvinyl alcohol so as to maintain the shape exemplified in FIG. 2C, thereby increasing the viscosity of 10 kPa·s or more. Colloidal silica has a nature in which the adhesive force increases by a dehydration reaction with an increase in temperature and colloidal silica does not undergo the dehydration reaction at a temperature lower than the finally reached temperature. For this reason, a temperature T1 required for adhesion curing of the adhesive member 202 is preferably set at a temperature (for example, about 210° C.) higher than the temperature in the scintillator deposition process. When removing the sensor units 109, a diluted aqueous solution of sodium carbonate can be used as the chemical agent P. Note that since the aqueous resin is dissolved with polyvinyl alcohol or the like, the chemical agent P is preferably adjusted to a temperature of about 5° C. to 80° C. and used.

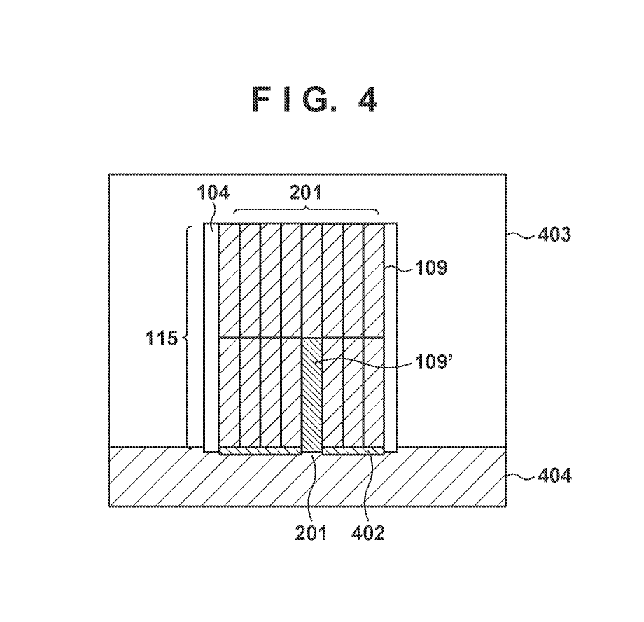

As exemplified in FIG. 4, the chemical agent P may be injected into each space sp by using a pressure difference between the space sp and the external pressure. FIG. 4 is a view for explaining a method of injecting the chemical agent P. Each opening 201 corresponding to the sensor unit 109 except the removal target sensor unit (to be shown as a sensor unit 109′) is sealed with, for example, a liquefied gasket 402. The liquefied gasket 402 can be made of a member which prevents permeation of a solution 404 of the chemical agent P and facilitates peeling. For example, a fluorine-based liquefied gasket 1119 series available from ThreeBond can be used for the liquefied gasket 402. Note that, as exemplified in FIG. 4, when sensor units of one line out of the sensor units 109 of two lines are removal targets, the liquefied gasket 402 is formed on the sensor units of the one line.

Next, the sensor panel 115 is placed in a pressure reducing chamber 403 charged with the solution 404 in advance, so that the sensor unit 109′ faces downward the side of the chemical agent 404). The interior of the chamber 403 is evacuated. After that, as exemplified in FIG. 4, the sensor panel 115 is moved so that the opening 201 of the space sp corresponding to the sensor unit 109′ is dipped below the liquid level of the solution 404. While this state is kept maintained, the pressure in the chamber 403 returns to the atmospheric pressure.

According to this method, a pressure difference is generated between the space sp and the external pressure, and the space sp corresponding to the sensor unit 109′ is filled with the chemical solution 404.

According to this method, in order to effectively inject the solution 404 to the space sp, for example, a solvent-resistant fiber may be arranged in the space sp. This makes it possible to advantageously fill the space sp with the solution 404 by a capillary phenomenon effectively and dissolve the adhesive member 202. The fiber may further have heat resistance (for example, 210° C. or more). For example, glass wool or a paraamido fiber technora available from TEIJIN can be used as the fiber.

In addition, the chemical agent P may be injected into the space sp using, for example, a microsylinge as the method of injecting the chemical agent P into each space sp. In this case, the height of the support portion 110 is set to be, for example, about 500 μm or more to facilitate injection of the chemical agent P into each space sp.

As described above, according to this embodiment, the chemical agent P for dissolving each adhesive member 202 can be injected through, for example, the corresponding opening 201, into the corresponding space sp contacting the sensor unit 109 swerving as the removal target out of the plurality of sensor units 109. Out of the plurality of sensor units 109, only the sensor unit 109 serving as the removal target can be individually removed from the support portion 110. This embodiment is advantageous in selectively removing some sensor units 109 from the support portion 110 which supports the plurality of sensor units 109. For example, as a result of inspection of each sensor unit 109, if a predetermined reference is not satisfied, the removal target is removed by the method exemplified above and replaced with another sensor unit. In addition, the method of manufacturing the radiation imaging apparatus 11 is advantageous in forming a heat-resistive sensor panel It is also possible to form the scintillator 106 on the sensor panel 115 by the deposition method (a so-called direct formation method). Therefore, this embodiment is advantageous in improving the sensitivity of the radiation imaging apparatus 11 and the MTF.

### Second Embodiment

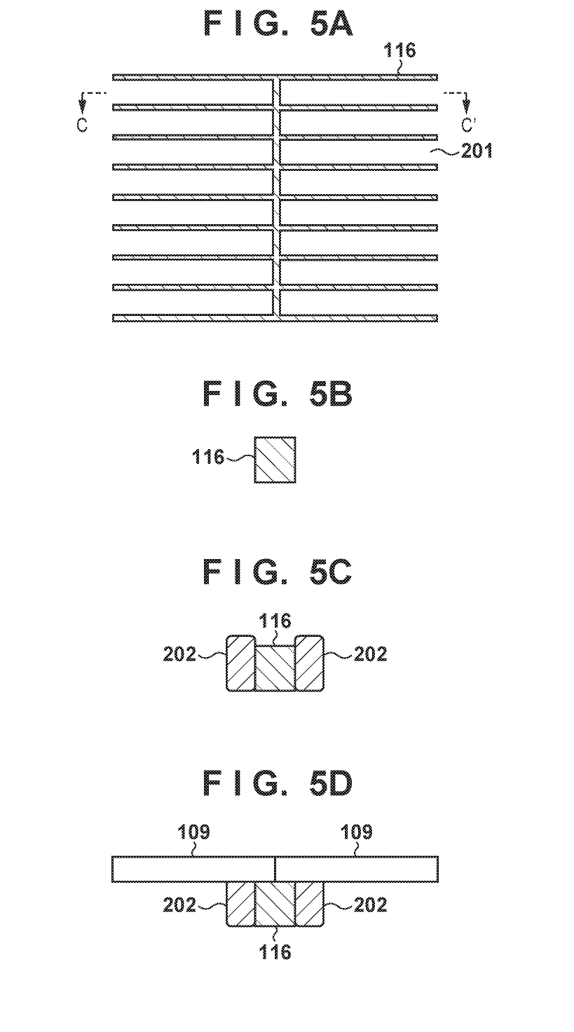

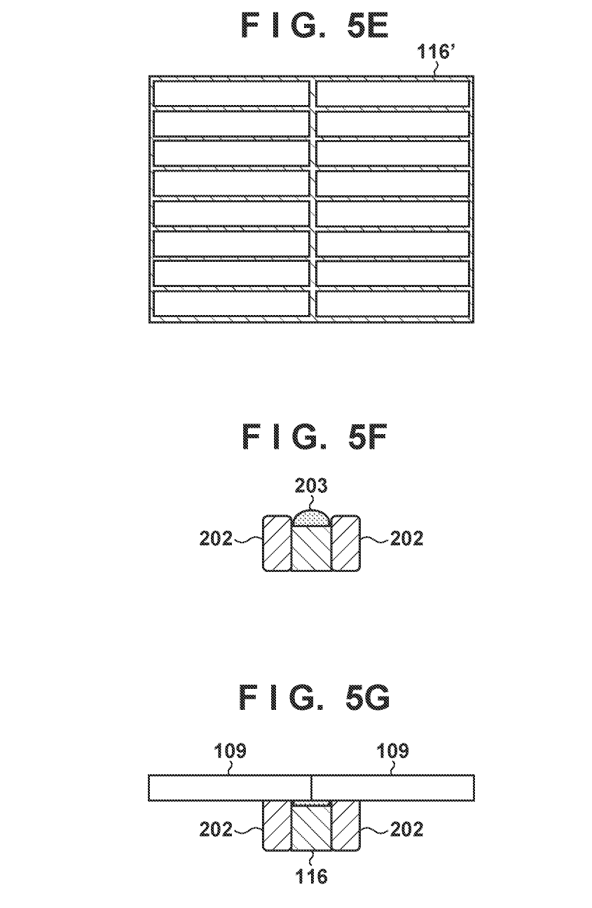

The second embodiment will be described with reference to FIGS. 5A to 5G. The first embodiment has exemplified the arrangement in which the plurality of sensor units 109 are supported by the lattice-shaped support portion 110 formed on the base 104. However, it suffices that a space sp for injecting a chemical agent P is formed so as to individually remove each sensor unit 109. The present invention is not limited to the arrangement of the first embodiment. For example, the radiation imaging apparatus 11 may have an arrangement in which the apparatus does not include a base 104, and a chemical agent P can be injected into a space sp from the lower surface side.

FIG. 5A is a schematic view showing an arrangement example of a support portion 116 according to this embodiment when viewed from the above. The support portion 116 has the same arrangement as that of the support portion 110 of the first embodiment. FIGS. 5B to 5D are schematic views showing the manufacturing steps of a sensor panel 115 for the sectional view along a outline D-D′ in the same manner as in the first embodiment (FIGS. 2B to 2D). As exemplified in FIG. 5C, the adhesive members 202 are arranged on the side surfaces of the support portion 116. The upper surface of each adhesive member 202 can be higher than the upper surface of the support portion 116. After that, in the same manner as in the first embodiment, the plurality of sensor panels 109 are arranged on the support portion 116. With this arrangement, the lower surface side of each space sp is open. It is possible to individually inject the chemical agent P into each space sp. The effect as in the first embodiment is obtained.

Since the chemical agent P can be injected into the space sp from the lower surface side, the support portion 116 need not be arranged in the end region of the opening 201. As shown in FIG. 5E, a support portion 116′ having an outer frame may be used in place of the support portion 116 with this arrangement, the support portion 116′ has a higher mechanical strength than that of the support portion 116.

In addition, as exemplified in FIGS. 5F and 5G, to adjust the surface levels of the support portion 116 and the adhesive members 202, an elastic member 203 may be arranged on the upper surface of the support portion 116 in the same manner as in the first embodiment (FIGS. 2E and 2F). The support portion 116 itself may be made of the same material as that of the elastic member 203. In this case, the upper surface of the adhesive members 202 may be lower than the upper surface of the support portion 116.

As described above, this embodiment is advantageous in selectively removing some sensor units 109 from the support portion 116 which supports the plurality of sensor units in the same manner as in the first embodiment.

### Third Embodiment

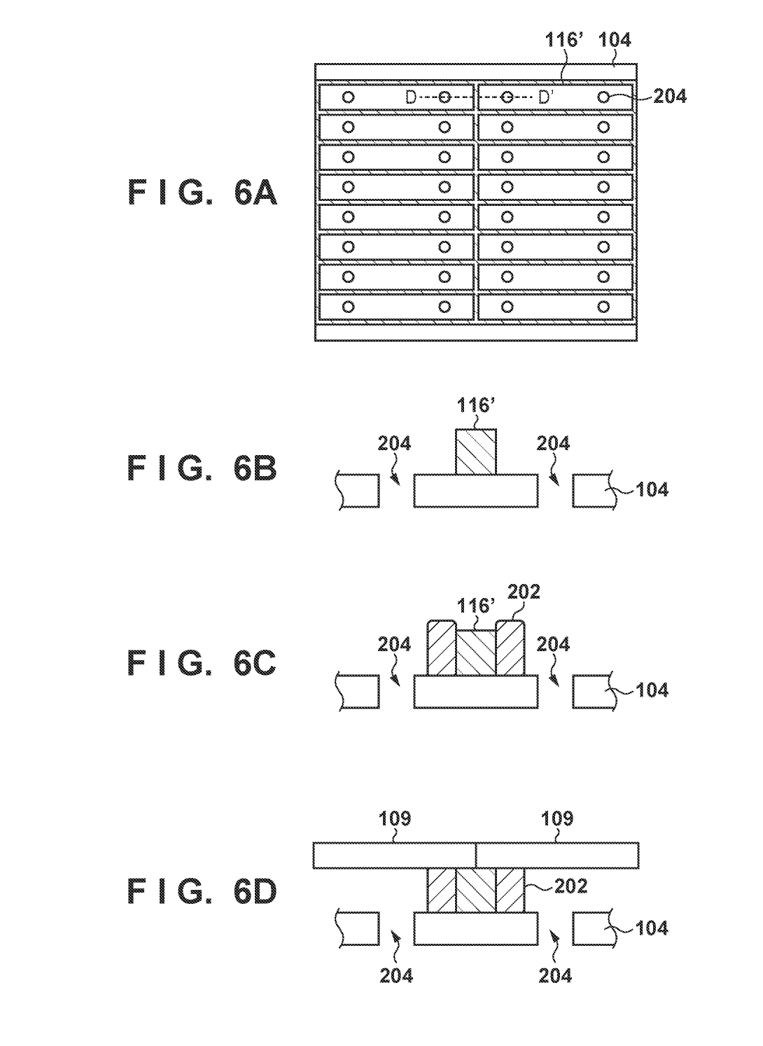

The third embodiment will be described with reference to FIGS. 6A to 6D. The first embodiment has exemplified the mode in which the chemical agent P is injected into the space sp via the opening 201. However, it suffices that the chemical agent P can be injected into each space sp. For example, as shown in FIGS. 6A to 6D, an arrangement using a base 104′ having an opening 204 (through hole) extending from the upper surface to the lower surface may be used.

FIG. 6A is a schematic view showing an arrangement example of a support portion 110 and a base 104′. FIGS. 6B to 6D are schematic views showing the manufacturing steps of a sensor panel 115 for the sectional structure along a outline E-E′ in the same manner as in the first embodiment (FIGS. 2B to 2D). According to this embodiment, the chemical agent P can be injected into the space sp from the opening 204 formed in the base 104′.

Note that since injection of the chemical agent P into the space sp is performed from the lower surface side of the base 104′, the opening 201 need not be arranged in the end region of the opening 201 in the same manner as in the second embodiment. According to this embodiment as well, a support portion 116 having an outer frame can be used.

At least two openings 204 are preferably formed in each space sp. With this arrangement, when injecting the chemical agent P into the space sp, one of the openings functions as an injection hole of the chemical agent P, and the other opening functions as an air hole, thereby facilitating the injection of the chemical agent P into the space sp. Similarly, when discharging the chemical agent P from the space sp, one of the openings functions as a discharge hole of the chemical agent P, and the other opening functions as an air hole, thereby facilitating the discharge of the chemical agent P from the space sp.

As described above, this embodiment is advantageous in selectively removing some sensor units 109 from a support portion 116 which supports a plurality of sensor units 109 in the same manner as in the first and second embodiments.

### Fourth Embodiment

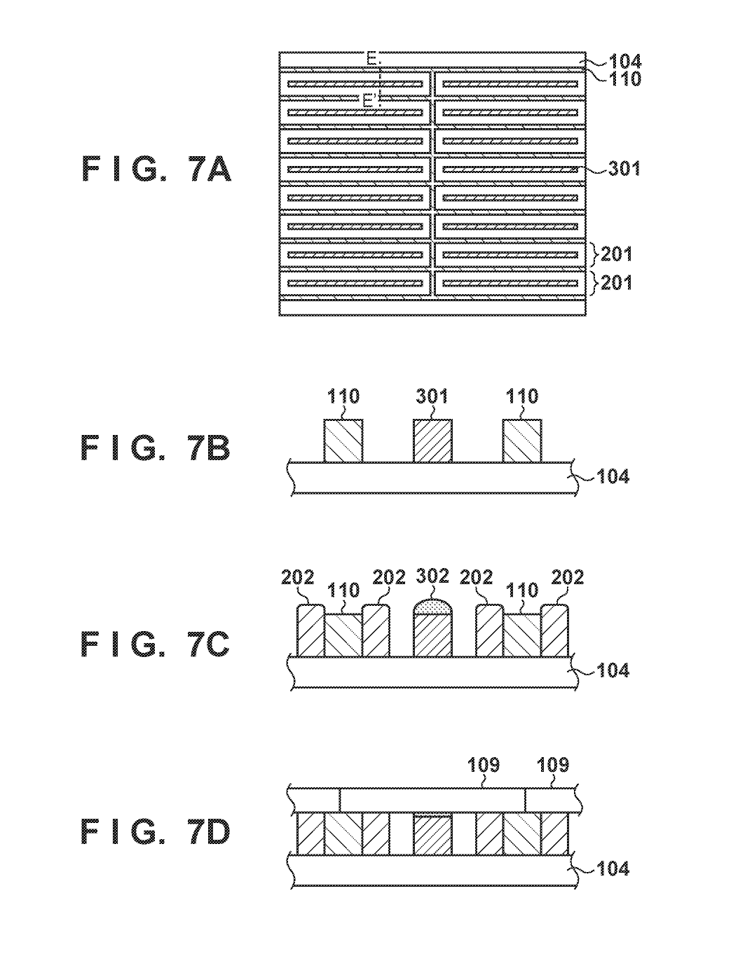

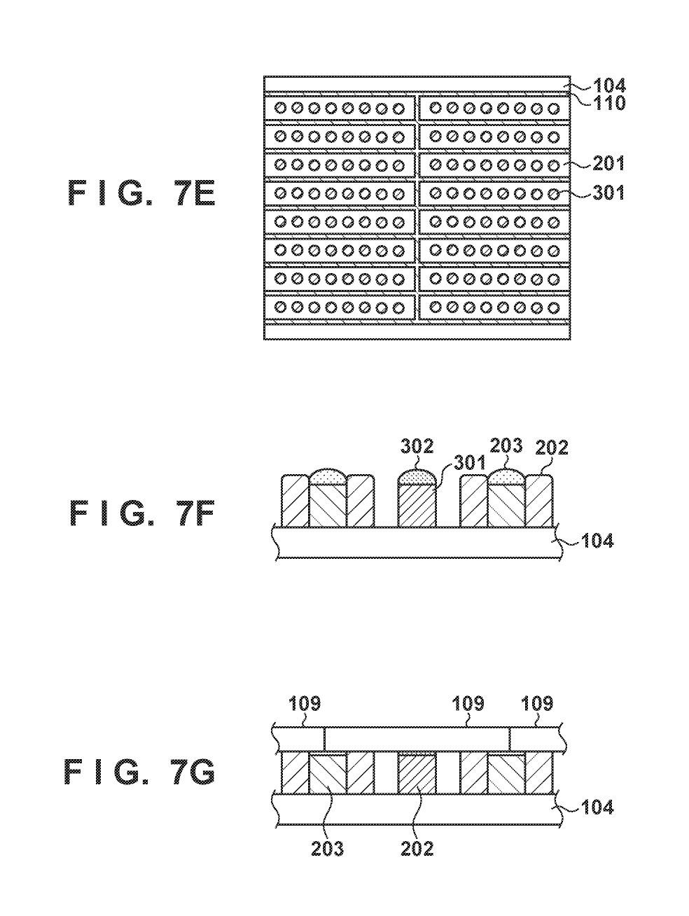

The fourth embodiment will be described with reference to FIGS. 7A to 7G. Each embodiment described above has exemplified the lattice-shaped support portion 110, 116, or 116′. A radiation imaging apparatus 11 further includes a second support portion 301, as exemplified in FIGS. 7A to 7G.

FIG. 7A is a schematic view showing an arrangement example of support portions 110 and 301 and a base 104. When a space sp is, for example, rectangular when viewed from the above, the support portion 301 may be arranged linearly along the long-side direction. Each support portion 301 may be arranged to form one or more lines in each space sp. As shown in FIG. 7B, the support portion 301 may be formed so that a plurality of columnar members are arranged in each space sp. Note that although the plurality of columnar members are arranged in a line, but may be arranged in two or more lines.

FIGS. 7C to 7E are schematic views showing the manufacturing steps of a sensor panel 115 for the sectional structure along a outline E-E′ as in the first embodiment (FIGS. 2B to 2D). According to this embodiment, adhesive members 202 are formed on the side surfaces of a support portion 101 as in the first embodiment. At the same time, as exemplified in FIG. 7D, a second adhesive member 302 for bonding each sensor unit 109 and the corresponding support portion 301 is formed on the corresponding support portion 301.

When a heat curing resin is used for the adhesive members 202 and 302, materials may be selected so that a curing temperature T1 of the adhesive member 202 is set lower than a curing temperature T2 of the adhesive member 302. With this arrangement, as exemplified in FIG. 7E, when arranging the sensor unit 109 on the support portions 110 and 301, for example, the temperatures T1 and T2 may be sequentially increased to bond the support portions 110 and 301. More specifically, a heat curable resin which can cure at a lower temperature is used as the material for the adhesive member 202 formed on the upper surface of the support portion 110. A adhesive which can cure at a high temperature and has heat resistance is used as the material for the adhesive member 302 formed on the upper surface of the support portion 301. After the heights and positions of the respective sensor units 109 are adjusted, the adhesive members 202 formed on the upper surface of the support portion 110 are cured at the temperature T1. After that, once cooling is performed, overheating is then performed. The adhesive member 302 formed on the upper surface of the support. portion 301 is cured at the temperature T2. This makes it possible to obtain a sensor substrate 119 which stands high temperatures when forming the scintillator with high accuracy by which the height and position of the sensor unit 109 have been adjusted. In this case, a thermoplastic resin which is melted at about 100° C. is used for the adhesive member 202. For example, a 80 series available from TECHNO ALPHA can be used for the adhesive member 202.

For the adhesive member 302, a material is selected such that the chemical agent P does not enter the space sp corresponding to an adjacent sensor unit 109 when the sensor unit 109 as the removal target is to be removed. For example, when the solution of a chemical agent P is used, an aqueous adhesive agent is used so as not to permeate the solution into the space sp. For example, an aqueous solution containing an aqueous resin and an adhesive material in which an adhesive force is generated by dehydration condensation of a silanol group or alkoxy group can be used.

In addition, as exemplified in FIGS. 7E and 7F, an elastic member 203 may be arranged on the upper surface of the support portion 110 in order to adjust the surface levels between the support portion 116 and the adhesive member 202 in the same manner as in the first embodiment (FIGS. 2E and 2F).

As described above, this embodiment is advantageous in selectively removing some sensor units 109 from the support portions 110 and 301 which support the plurality of sensor units 109 in the same manner as in the first, second, and third embodiments. In addition, this embodiment is advantageous in improving, by further using the support portion 301, the reliability of the radiation imaging apparatus 11 since the mechanical strength of the sensor panel 115 is improved.

The four embodiments have been described above, but the present invention is not limited to these. The changes can be made appropriately in accordance with the purpose, state, application, and other specifications and can be made by other embodiments. For example, it suffices that the chemical agent P can be injected into the corresponding space sp to individually remove each sensor unit 109 from the support portion 110. The present invention is not limited to the arrangements of the respective embodiments. For example, each embodiment has exemplified an arrangement in which each space sp is partitioned such that a ratio of the number of spaces sp and the number of sensor units 109 is set to 1:1. However, the ratio can be k:1 (k is an integer of 2 or more). In this case, the plurality of sensor units 109 can be arranged such that the boundary between the adjacent sensor units 109 need not come close to the upper surface of the support portion 110. In addition, the materials and parameters of the respective members can be changed and modified without departing from the scope of the present invention.

### Radiation Imaging System

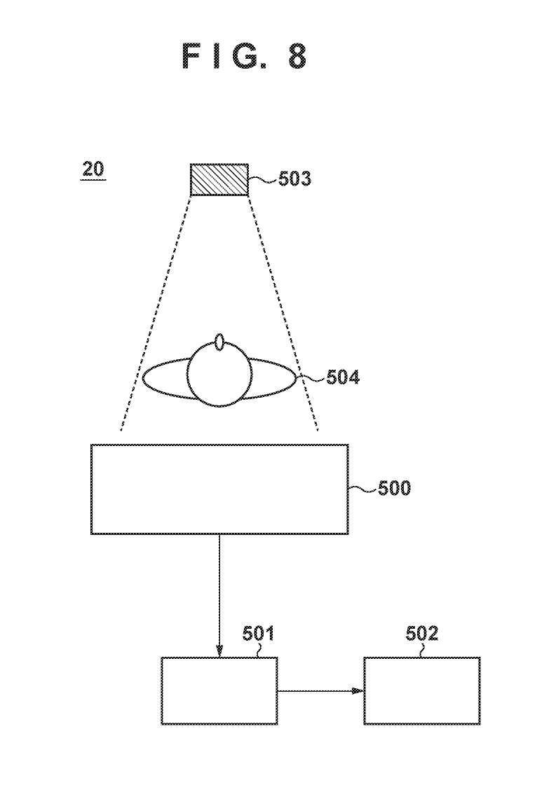

Radiation includes X-rays, α-rays, β-rays, and γ-rays. The radiation detection apparatus 11 is applicable to an imaging system. A radiation inspection apparatus 20 will be described as an arrangement example of a radiation imaging system with reference to FIG. 8. The radiation inspection apparatus 20 includes, for example, a housing 500 including a radiation imaging apparatus 11, a signal processing unit 501 including an image processor, a display unit 502 including a display, and a radiation source 503 for generating radiation. Radiation (X-rays as a typical example) emitted from the radiation source 503 passes through an object 504, and the radiation imaging apparatus 11 of the housing 500 detects the radiation containing interior information of the object 504. By using a radiation image thus obtained, for example, the signal processing unit 501 performs predetermined signal processing, thereby generating image data. This image data is displayed on the display unit 502.

The four embodiments and the application example to the imaging system have been described above. The present invention is not limited to these. Changes can be made appropriately for the purpose, state, application, function, and other specifications. The present invention can be practiced by other embodiments.

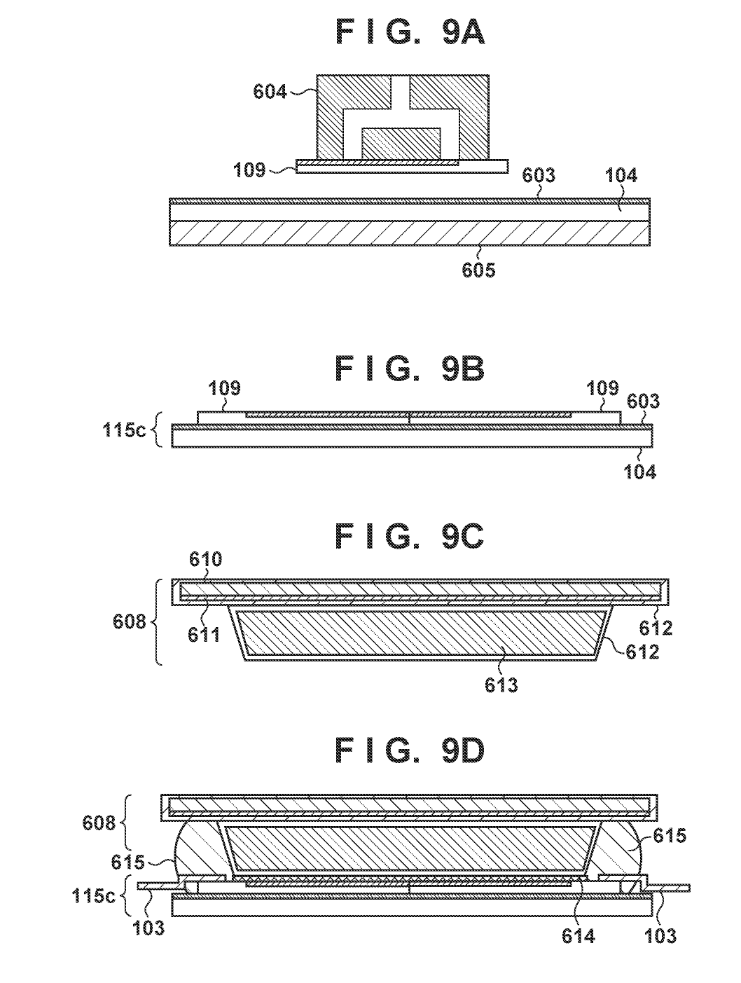

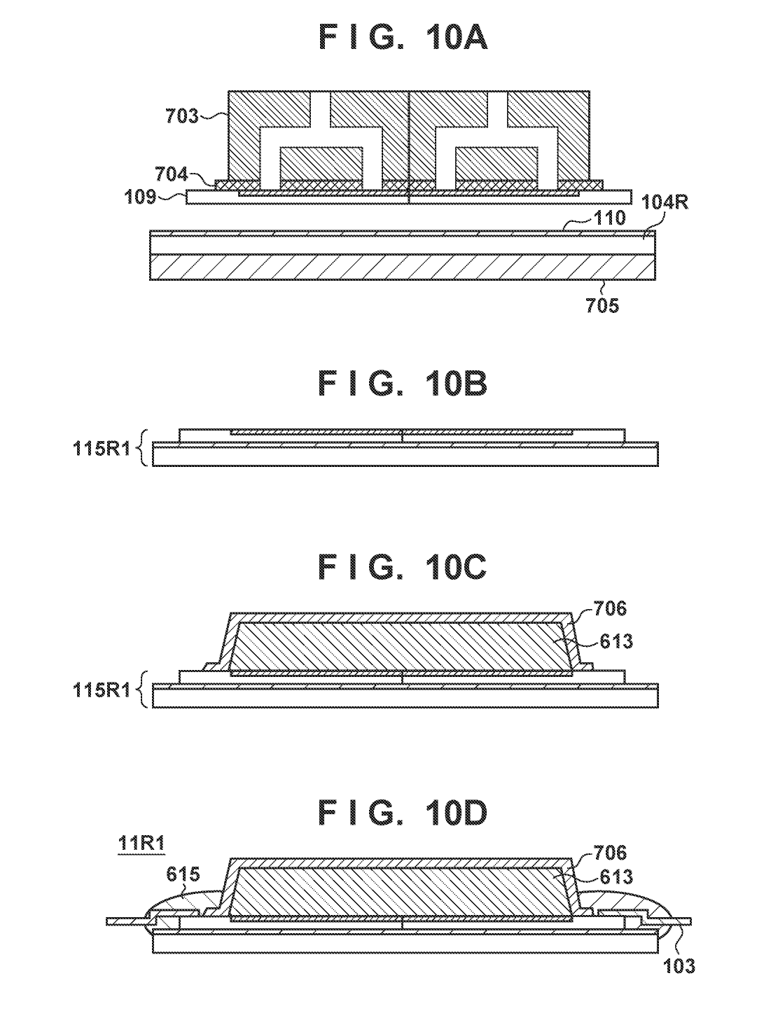

The first to fourth examples (examples respectively corresponding to the first to fourth embodiments) of the present invention and a comparative example compared with the present invention will be described with reference to FIGS. 9A to 14B.

### COMPARATIVE EXAMPLE

A process for manufacturing a radiation imaging apparatus 11_{c} will be described as a comparative example with reference to FIGS. 9A to 9D. As exemplified in FIG. 9A, a base 104 is placed on a stage 605, and a first adhesive layer 603 is formed on the base 104. After that, sensor units 109 are arranged on the base 104 using a movable chuck stage 604 and fixed by the adhesive layer 603. In this manner, as exemplified in FIG. 9B, the plurality of sensor units 109 are arranged on the base 104.

The sensor unit 109 is a CMOS sensor chip obtained by dividing a silicon wafer by dicing. Each sensor unit 109 (for example, a size is 140 mm×20 mm) includes 864×128 sensors arranged in the form of an array. An amplifier for amplifying a signal from each sensor is arranged at an end region of the array. A glass substrate was prepared as the base 104. A heat-peeling adhesive layer is used as the adhesive layer 603. For example, a two-side separator can be used as a peeling member.

Four sensor panels 115C in which 28 (2 columns×14 rows) sensor units 109 were arranged were formed, and a test was conducted for three of the four sensor panels. Note that 1,728×1,792 sensors are arranged in each sensor panel 115C.

A peeling test was conducted for the entire panel as a first sample 115C₁ out of the four sensor panels 115C. When the sample 115C₁ was placed on a hot plate and heated to 120° C., all the sensor units 109 were peeled from the base 104.

A peeling test was conducted for each unit using a second sample 115C₂ out of the four sensor panels 115C. A rubber heater was placed on the back surface position (the lower surface side of the sample 115C₂, that is, the base 104 side) of one sensor unit (this unit is given as a sensor unit 109a) serving as a test target. The sensor unit 109a was heated (120° C.) during temperature adjustment using a thermocouple. As a result, the sensor unit 109a was peeled, and five sensor units 109 adjacent to the sensor unit 109a were also peeled. It was confirmed that it was difficult to peel sensor units for each unit.

A scintillator deposition test was conducted using a third sample 115C₃ out of the four sensor panels 115C. The sample 115C₃ was placed on a holder in a deposition apparatus chamber, a mask was set so as to perform deposition in an imaging region, and the sample 115C₃ was rotated (30 rpm). After that, the chamber was set in an almost vacuum state (10⁻³ Pa), and the chamber was filled with argon (Ar). The sample 115C₃ was heated by a lamp heater (200° C., 10⁻¹ Pa) to perform deposition (2 hrs) using thallium-activated cesium iodide (CsI:Tl). After the deposition process, the interior of the chamber was cooled (50° C.), and the sample 115C₃ was unloaded from the chamber. As a result, all the sensor units 109 were peeled from the base 104 in the sample 115C₃. That is, it was confirmed that it was difficult to form the scintillator on the sensor panel 115C by a so-called direct forming method.

A scintillator was formed in a fourth sample 115C₄ out of the four sensor panels 115C by the direct forming method. More specifically, the sample 115C₄ was placed on the stage 605, and a second adhesive layer 614 was formed on the sample 115C₄.

After that, as exemplified in FIG. 9C, a scintillator panel 608 was prepared. As exemplified in FIG. 9D, the scintillator panel 608 was fixed to the sample 115C₄ via the adhesive layer 614.

The scintillator panel 608 exemplified in FIG. 9C is obtained using a known manufacturing process. More specifically, an aluminum film 611 (film thickness of about 250 μm) was formed on, for example, an amorphous carbon substrate 610 (thickness of about 1 mm). After that, the amorphous carbon substrate 610 and the aluminum film 611 were covered with polyparaxylene 612 (thickness of about 12.5 μm). A CsI:Tl scintillator 613 (thickness of about 550 μm) was formed by deposition on the aluminum film 611 side. Thallium (Tl) was adjusted to 0.5 mol % with respect to cesium iodide (CsI). The entire structure including the scintillator 613 was covered with the polyparaxylene 612 (thickness of about 12.5 μm).

Finally, the flexible printed board 103 was connected to the electrode portion of the sample 115C₄ to which the scintillator panel 608 was fixed, and the resultant structure was sealed with a silicone-based sealing resin 615. As described above, a scintillator was formed on the sample 115C₄ by a so-called direct forming method, thereby obtaining the radiation imaging apparatus 11_{c}.

The sensitivity evaluation and MTF evaluation of the radiation imaging apparatus 11_{c} were conducted. Upon irradiation of an X-ray pulse (49 kV, 10 mA, 40 ms), the sensitivity was 5,900 LSB, and the 2-LP/mm MTF was 0.320.

### First Example

A radiation imaging apparatus according to the first embodiment was manufactured in the first example. FIGS. 10A to 10D are schematic views showing the mode of steps in manufacturing the radiation imaging apparatus.

A glass substrate having 287 mm×302 mm×1.2 mm thick was prepared and set in a substrate cleaning machine. Cleaning was performed in the order of acetone immersive ultrasonic cleaning, isopropyl alcohol immersive ultrasonic cleaning, and neutral detergent solution brushing cleaning. The flowing water rising process was performed for the glass substrate using pure water, and the glass substrate was dried using a warm air knife. A dry film resist (DFR) was laminated on the glass substrate. An alkali development type negative dry film having a resistance to hydrofluoric acid was used as the DFR. More specifically, a glass etching DRR available from Mitsubishi Paper Mills was used. A UV exposure process was performed for the glass substrate with this DFR using a patterning mask, and then the development process was performed using a diluted aqueous alkali solution. After that, the resultant structure was baked at 180° C. for 2 hrs. The etching was then performed using hydrofluoric acid. The resultant structure was cleaned with water and dried again. Finally, the DFR was peeled using a resist peeling solution. As described above, a plurality of glass bases 104R1 each having an upper surface with a support portion 110 whose convex portion drew a lattice shape were manufactured.

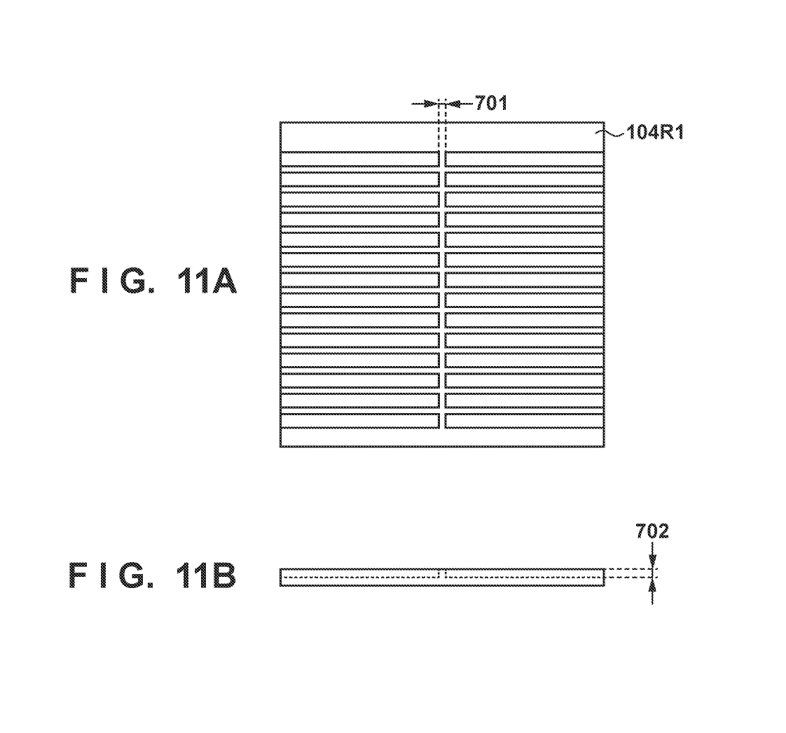

FIG. 11A is a schematic view showing the glass base 104R1 when viewed from the above. FIG. 11B is its side view. A width 701 of (the convex portion of) the support portion 110 is 3 mm, and its depth 702 is 0.6 mm.

On the other hand, as shown in FIG. 10A, 28 sensor units 109 (the same as the comparative example) were fixed via a fluorine-based protective film 704 (for example, NITOFLON available from Nitto) to a first stage 703 which fixed a target object by vacuum chucking.

In addition, as shown in FIG. 10A, a second stage 705 for fixing the target object by another vacuum chucking was fixed to the glass base 104R1.

After that, an adhesive members 202 were applied to (the side surfaces of the convex portion) the glass base 104R1 using a dispenser. TB2285 available to ThreeBond was used as the adhesive member 202 in a first sample 104R1₁. For a second sample 104R1₂ and a third sample 104R1₃, a composite aqueous adhesive agent in which SNONTEX silica C (150 parts by weight) available from Nissan Chemical Industries was dissolved in pure water (100 parts by weight), and Gohsenol available from NIPPON GOHSEI was dissolved in the resultant mixture was used. At this time, the viscosity at 25° C. was adjusted to be 10 kPa·s. For the third sample 104R1₃, a PM series available from CEMEDINE was applied as the elastic member 203 to the upper surface of the convex portion using a dispenser (see FIG. 2E). The resultant structure was then dried (room temperature, 24 hrs).

After applying the adhesive members 202, a CCD camera performed alignment, and the stage 703 facing the stage 705 was moved downward until the sensor units 109 were brought into contact with the glass base 104R1. In this manner, as shown in FIG. 10B, the sensor units 109 were fixed to the glass base 104R1. Note that this fixing was performed by adhering and curing the adhesive members 202 by heating, and this heating was performed using ceramic heaters arranged in the stages 703 and 705. The sample 104R1₁ was heated to 150° C., and the samples 104R1₂ and 104R1₃ were heated to 210° C.

A peeling test was conducted for sensor panels 115R1₁ to 115R1₃ (115R1) manufactured using the thus obtained samples 104R1₁ to 104R1₃ in the same manner as in the comparative example. As described in the first embodiment, a space sp is formed under each sensor unit 109 in each of the sensor panels 115R1₁ to 115R1₃. The peeling test was performed by injecting a chemical agent P into the space sp using a microsylinge. Note that as the chemical agent P, acetone was used for the sensor panel 115R1₁, and a 5% sodium carbonate solution (65° C.) was used for the sensor panels 115R1₂ and 115R1₃. In any of the sensor panels 115R1₁ to 115R1₃, after about 5 min, only the sensor units 109 as the removal targets floated from the glass substrate 104R1 and could be removed.

A peeling test was conducted by injecting the chemical agent P into each space sp using the microsylinge after inserting a glass fiber into the space sp of each of the sensor panels 115R1₁ to 115R1₃. As a result, after 2 to 3 min, only the sensor unit 109 as the removal target floated from the glass substrate 104P1 and could be removed. That is, when the fiber was provided in the space sp, removal of the sensor unit 109 as the removal target could be facilitated.

A peeling test was conducted by sealing, with the liquefied gasket, the opening 201 corresponding to the sensor unit 109 except for the sensor unit serving as the removal target and injecting the chemical agent P into each space sp using a pressure difference between the space sp and the external pressure. As a result of filling the chemical agent P into the space sp in the sequence described in the first embodiment, after 1 to 2 min, only the sensor unit 109 serving as the removal target floated from the glass substrate 104R1 and could be removed from the sensor unit 109.

Next, as exemplified in FIG. 10C, each of other sensor panels 115R1₁ to 115R1₃ was prepared, and a CsI:Tl scintillator 613 (thickness of about 550 μm) was formed on each sensor panel by the direct formation method. In the same manner as in the comparative example, thallium (Tl) was adjusted such that thallium was set to 0.5 mol % with respect to cesium iodide (CsI). In the deposition process of the scintillator 613, the sensor unit 109 neither floated nor were peeled from the glass base 104R1.

After that, a scintillator protective film 706 (AlPET sheet) obtained by depositing an aluminum (Al) film having a thickness of about 250 nm on polyethylene telephthalate (PET) having a film thickness of about 25 μm was formed to cover a scintillator 613. Note that a film made of a thermoplastic resin having a film thickness of about 50 μm was formed in advance before forming a scintillator protective film 706 in order to improve the bonding strength between the scintillator 613 and each of the sensor panels 115R1₁ to 115R1₃. After the scintillator protective film 706 was formed, the resultant structure was heated at 80° C. to 100° C. using a vacuum laminator apparatus, thereby improving the adhesion strength between the scintillator protective film 706 and the scintillator 613 and the sensor panels 115R1₁ to 115R1₃.

After that, as exemplified in FIG. 10D, in order to prevent the scintillator 613 from the moisture, 100° C. heat sealing (thermocompression bonding) was performed for the peripheral region of the scintillator 613. In addition, after that, the flexible printed board 103 was connected to the electrode portion of each of the sensor panels 115R1₁ to 115R1₃, and the periphery of the electrode portion was sealed with a silicone-based resin 615.

As described above, the sensitivity evaluation and the MTF evaluation were conducted for the radiation imaging apparatuses 11R1₁ to 11R1₃ (11R1) manufactured using the sensor panels 115R1₁ to 115R1₃ in the same manner as in the comparative example. As for the radiation imaging apparatus 11R1₁, the sensitivity was 6,054 LSB, and the 2 LP/mm MTF was 0.360. AS for radiation imaging apparatus 11R1₂, the sensitivity was 6,051 LSB, and the 2 LP/mm MTF was 0.361. As for radiation imaging apparatus 11R1₃, the sensitivity was 6,056 LSB, and the 2 LP/mm MTF was 0.360. That is, the sensitivities and MTFs of the radiation imaging apparatuses 11R1₁ to 11R1₃ are better than those of the comparative example.

### Second Example

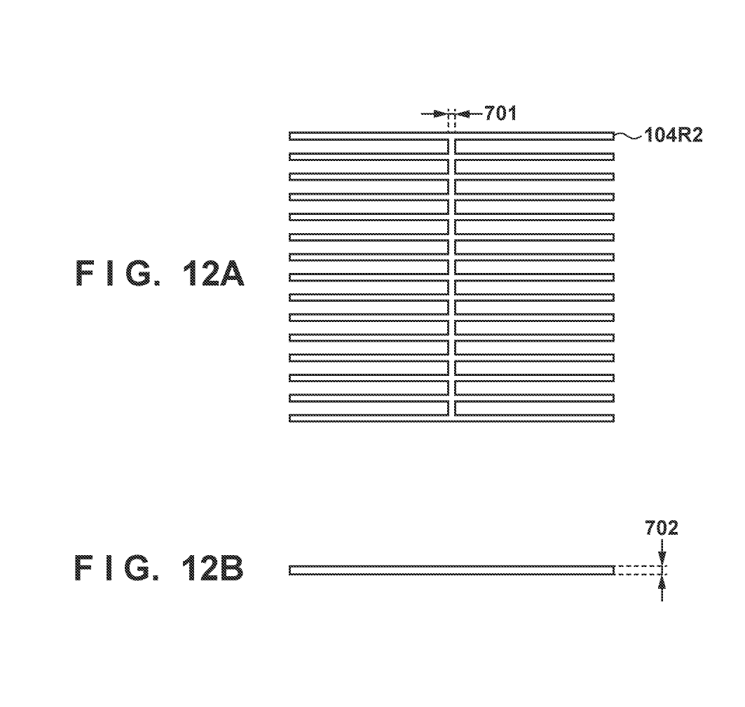

In the second example, a radiation imaging apparatus according to the second embodiment was manufactured. FIG. 12A is a schematic view showing a glass base 104R2 when viewed from the above. FIG. 12B shows its side view. A glass substrate having 207 mm×302 mm×0.6 mm thick was prepared. After that, the glass base 104R2 including a lattice-shaped support portion was manufactured in the same method as in the first example. A width 701 of each portion of the glass base 104R2 was 3 mm, and its thickness 702 (the thickness of the glass base 104R2 itself) was 0.6 mm. In this manner, a plurality of sensor panels 115R2₁ to 115R2₃ (115R2) were manufactured using the same procedure as in the first example.

A peeling test was conducted by injecting a chemical agent P (the same chemical agent as in the first example) into a space sp using a micropipette for each of the sensor panels 115R2₁ to 115R2₃ manufactured as described above. Injection of the chemical agent P was performed from the lower surface side of each of the sensor panels 115R2₁ to 115R2₃. As a result, after about 1 min, only the sensor unit 109 serving as the removal target floated from the glass substrate 104R2 and could be removed.

Next, each of other sensor panels 115R2₁ to 115R2₃ was prepared, and a CsI:Tl scintillator 613 (thickness of about 550 μm) was formed on each sensor panel in the same manner as in the first example. In the deposition process of the scintillator 613, floating and peeling of the sensor unit 109 from the glass base 104R2 were not found.

After that, radiation imaging apparatuses 11R2₁ to 11R2₃ (11R2) were manufactured in the same sequence as described above (formation of a scintillator protective film 706, connection of a flexible printed board 103, and the like). The sensitivity evaluation and the MTF evaluation of these radiation imaging apparatuses were performed.

As for the radiation imaging apparatus 11R2₁, the sensitivity was 6,052 LSB, and the 2 LP/mm MTF was 0.361. As for radiation imaging apparatus 11R2₂, the sensitivity was 6,054 LSB, and the 2 LP/mm MTF was 0.360. As for radiation imaging apparatus 1192₃, the sensitivity was 6,053 LSB, and the 2 LP/mm MTF was 0.360. That is, the sensitivities and MTFs of the radiation imaging apparatuses 11R2₁ to 11R2₃ are better than those of the comparative example.

### Third Example

A radiation imaging apparatus according to the third embodiment was manufactured in the third example. First of all, a glass substrate having 287 mm×302 mm×1.2 mm thick was prepared, a glass base was manufactured using the same procedure as in the first example, and two openings 204 were formed in each space sp in the glass base. The glass base thus obtained is called a glass base 104R3.

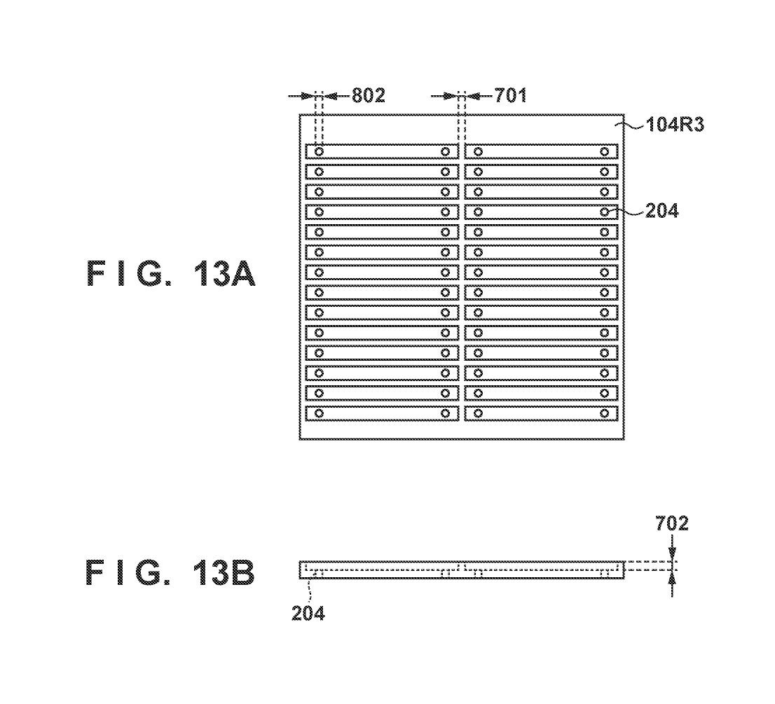

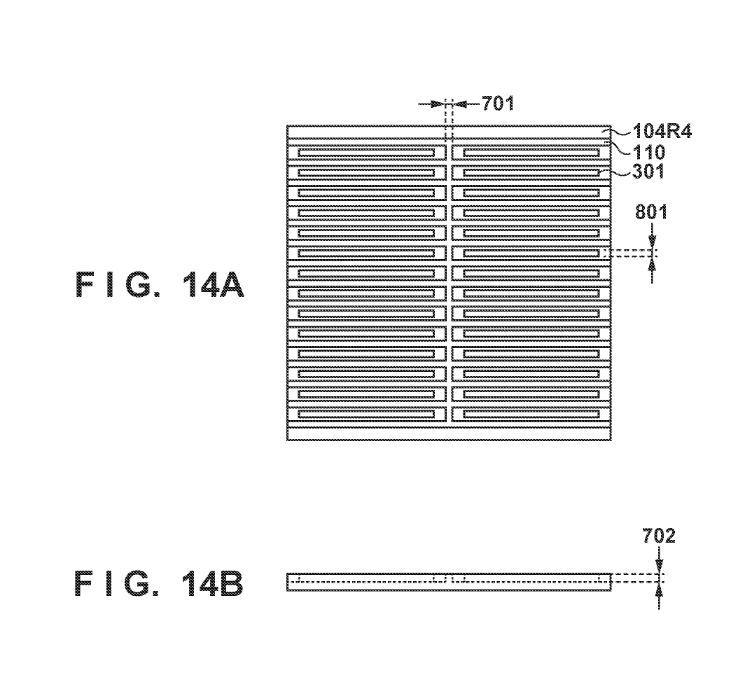

FIG. 13A is a schematic view showing the glass base 104R3 when viewed from the above. FIG. 13B is its side view. A diameter 802 of each opening 204 was 5 mm. After that, a plurality of sensor panels 115R3₁ to 115R3₃ (115R3) were manufactured using the same procedure as in the first example.

A peeling test was conducted for each of the sensor panels 115R3₁ to 115R3₃ by injecting a chemical agent P (a chemical agent as in the first example) into each space sp using a micropipette. The injection of the chemical agent P was performed through each opening 204. As a result, after about 1 min, only a sensor unit 109 serving as a removal target floated from the corresponding glass substrate 104R3 and could be removed from the corresponding sensor unit 109.

Next, each of other sensor panels 115R3₁ to 115R3₃ were prepared, and a CsI:Tl scintillator 613 (a thickness of about 550 μm) was formed on each sensor panel in the same manner as in the first example. In the deposition process of the scintillator 613, floating and peeling of the sensor unit 109 from the glass base 104R3 were not observed.

After that, in the same procedure as described above (formation of a scintillator protective film 706, connection of a flexible printed board 103, and the like), radiation imaging apparatuses 11R3₁ to 11R3₃ (11R3) were manufactured, and the sensitivity evaluation and MFT evaluation were performed.

As for the radiation imaging apparatus 11R3₁, the sensitivity was 6,057 LSB, and the 2 LP/mm MTF was 0.359. As for the radiation imaging apparatus 11R3₂, the sensitivity was 6,050 LSB, and the 2 LP/mm MTF was 0.363. As for the radiation imaging apparatus 11R3₃, the sensitivity was 6,052 LSB, and the 2 LP/mm MTF was 0.360. The sensitivity and MTF of each of the radiation imaging apparatuses 11R3₁ to 11R3₃ were better than those of the comparative example.

### Fourth Example

A radiation imaging apparatus according to the fourth embodiment was manufactured in the fourth example. FIG. 14A is a schematic view showing a glass base 104R4 when viewed from the above. FIG. 14B is its side view. First of all, a glass substrate having 287 mm×302 mm×1.2 mm thick was prepared, and a glass base 104R4 having a second support portion 301 in addition to the support portions 110 was manufactured using the same procedure as in the first example. A width 801 of (the convex portion of) the second support portion 301 was 3 mm.

As for a first sample 104R₁, a 80 series available from TECHNO ALPHA was used for an adhesive member 202. As an adhesive member 302, a composite aqueous adhesive agent obtained by dissolving the SNOWTEX silica C (150 parts by weight) available from Nissan Chemical Industries in pure water (100 parts by weight) and further dissolving Gohsenol available from NIPPON GOHSEI in the resultant mixture was used. In this case, the viscosity of the adhesive agent at 25° C. was adjusted to be 10 kPa·s.

As for a second sample 104R4₂, the above-described composite aqueous adhesive agent was used for the adhesive members 202 and 302. As an elastic member 203, a PM series available from CEMEDINE was applied to the upper surface of the convex portion using a dispenser (see FIG. 2E) and was then dried (room temperature, 24 hrs). In this manner, a plurality of sensor panels 115R4₁ and 115R4₂ (115R4) were manufactured using the same procedure as in the first example.

A peeling test was conducted for each of the sensor panels 115R4₁ and 115R4₂ manufactured as described above by injecting a chemical agent P into each space sp using a microsylinge. A 5% sodium carbonate solution (65° C.) was used as the chemical agent P for the sensor panels 115R4₁ and 115R4₂. Injection of the chemical agent P was performed through each opening 201. As a result, after about 5 min, only a sensor unit 109 serving as a removal target floated from the glass substrate 104R4 and could be removed.

A peeling test was conducted by injecting the chemical agent P into each space sp using the microsylinge after glass fibers are inserted into the respective spaces sp of the sensor panels 115R4₁ and 115R4₂. As a result, after 2 to 3 min, each sensor unit 109 serving as a removal target floated from the glass substrate 104R1 and could be removed. That is, by providing the fibers in the respective spaces sp, removal of the sensor unit 109 serving as a removal target could be facilitated.

A peeling test was also conducted by sealing an opening 201 corresponding to the sensor unit 109 except for the sensor unit serving as a removal target and injecting the chemical agent P into each space sp using a pressure difference between the space sp and the external pressure. As a result of filling the space sp with the chemical agent P by using the same procedure as described above, after 1 to 2 min, only the sensor unit 109 serving as a removal target floated from the glass substrate 104R1 and could be removed.

After that, in the same procedure as described above (formation of a scintillator protective film 706, connection of a flexible printed board 103, and the like), radiation imaging apparatuses 11R4₁ and 11R4₂ (11R4) were manufactured, and the sensitivity evaluation and MFT evaluation were performed.

As for the radiation imaging apparatus 11R4₁, the sensitivity was 6,050 LSB, and the 2 LP/mm MTF was 0.360. As for the radiation imaging apparatus 11R4₂, the sensitivity was 6,055 LSB, and the 2 LP/mm MTF was 0.361. The sensitivity and MTF of each of the radiation imaging apparatuses 11R4₁ and 11R4₂ were better than those of the comparative example.

Each example described above is advantageous in selectively removing some sensor units 109 from the support, portion 110 which supports the plurality of sensor units 109. According to the radiation imaging apparatuses 11R1 to 11R4 of the respective examples, the heat-resistant sensor panels 115R1 to 115R4 could be obtained. The scintillators 106 could be formed on the sensor panels 115R1 to 115R4 by a so-called direct formation method. As a result, the sensitivity and MTF of each of the radiation imaging apparatuses 11R1 to 11R4 could be improved.

While the present invention has been described with reference to exemplary embodiments, it is to be understood that the invention is not Limited to the disclosed exemplary embodiments. The scope of the following claims is to be accorded the broadest interpretation so as to encompass all such modifications and equivalent structures and functions.

1. A radiation imaging apparatus comprising:
a plurality of sensor units each including a plurality of sensors;
a support portion having a lattice shape which partitions a region under the plurality of sensor units into a plurality of spaces and configured to support the plurality of sensor units from a side of lower surfaces of the plurality of sensor units; and
bonding members respectively arranged in the plurality of spaces and configured to bond the plurality of sensor units and the support portion.

2. The radiation imaging apparatus according to claim 1, wherein the bonding members are arranged to be in contact with the lower surfaces of the plurality of sensor units and surfaces in contact with the plurality of spaces.

3. The radiation imaging apparatus according to claim 2, wherein the bonding members are not arranged between the lower surfaces of the plurality of sensor units and an upper surface of the support portion.

4. The radiation imaging apparatus according to claim 2, further comprising an elastic member arranged between the lower surfaces of the plurality of sensor units and an upper surface of the support portion.

5. The radiation imaging apparatus according to claim 1, wherein
the bonding members are arranged in two lines between the lower surfaces of the plurality of sensor units and an upper surface of the support portion and on the upper surface of the support portion, and
the radiation imaging apparatus further comprises an elastic member arranged between the lower surfaces of the plurality of sensor units and the upper surface of the support portion and between the bonding members arranged in the two lines.

6. The radiation imaging apparatus according to claim 1, wherein the support portion is arranged so as to make at least one of the plurality of spaces correspond to one of the plurality of sensor units.

7. The radiation imaging apparatus according to claim 1, wherein the plurality of sensor units include a first sensor unit and a second sensor unit which are adjacent to each other, and a boundary between the first sensor unit and the second sensor unit comes close to the upper surface of the support portion.

8. The radiation imaging apparatus according to claim 1, further comprising a base arranged below the support portion, the base having an opening extending from the upper surface of the base to a lower surface thereof.

9. The radiation imaging apparatus according to claim 8, wherein the base further includes a second opening extending from the upper surface to the lower surface of the base.

10. The radiation imaging apparatus according to claim 1, further comprising:
a base arranged below the support portion; and
a second support portion arranged between the plurality of sensor units and the base in each of the plurality of spaces.

11. The radiation imaging apparatus according to claim 10, wherein
each of the plurality of spaces has a rectangular shape when viewed from above, and
the second support is formed linearly so as to form at least one line along a long-side direction of the rectangular shape.

12. The radiation imaging apparatus according to claim 10, wherein the second support portion includes a plurality of arrayed columnar members.

13. The radiation imaging apparatus according to claim 10, further comprising second bonding members arranged between the plurality of sensor units and the second support portion and configured to bond the plurality of sensor units and the second support portion.

14. The radiation imaging apparatus according to claim 13, wherein the bonding members and the second bonding members are made of a thermosetting resin, and a curing temperature of the bonding members is lower than that of the second bonding members.

15. A radiation inspection apparatus comprising:
a radiation imaging apparatus; and
a processing unit configured to process a signal from the radiation imaging apparatus, wherein
the radiation imaging apparatus comprises:
a plurality of sensor units each including a plurality of sensors;
a support portion having a lattice shape which partitions a region under the plurality of sensor units into a plurality of spaces and configured to support the plurality of sensor units from a side of lower surfaces of the plurality of sensor units; and
bonding members respectively arranged in the plurality of spaces and configured to bond the plurality of sensor units and the support portion.

16. A method of manufacturing a radiation imaging apparatus, the method including a step of arranging a plurality of sensor units each having a plurality of sensors on a support portion, wherein
the step includes:
a step of preparing the support portion having a lattice shape so as to partition a region under the plurality of sensor units into a plurality of spaces; and
a step of arranging the plurality of sensor units on the support portion and bonding the plurality of sensor units and the support portion using bonding members.

17. The method of manufacturing a radiation imaging apparatus according to claim 16, further comprising:
a step of testing the plurality of sensor units supported by the support portion; and
a step of removing at least one of the plurality of sensor units and replacing the at least one sensor unit with another sensor unit by injecting a chemical agent in which the bonding members are dissolved into at least one space with which at least one of the plurality of sensor units is in contact out of the plurality of spaces when a result of the test for the at least one of the plurality of sensor units does not satisfy a predetermined reference.

18. The method of manufacturing a radiation imaging apparatus according to claim 16, further comprising:
a step of forming a scintillator on the plurality of sensor units by a deposition method.
